(19) United States
(12) Patent Application Publication
(10) Pub. No.: US 2025/0393221 A1
(43) Pub. Date: Dec. 25, 2025

(54) SYSTEMS AND METHODS FOR PROVIDING POWER INTEGRITY TO FUNCTIONAL CIRCUITRY OF A SEMICONDUCTOR DEVICE

(71) Applicant: Xilinx, Inc., San Jose, CA (US)

(72) Inventor: Zachary Blair, San Jose, CA (US)

(73) Assignee: Xilinx, Inc., San Jose, CA (US)

(21) Appl. No.: 18/747,557

(22) Filed: Jun. 19, 2024

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0652; H01L 25/18; H01L 25/50; H01L 2224/08145; H01L 2224/80895; H01L 2224/80896; H01L 2924/1205; H01L 2924/1431; H01L 2924/1437; H01L 2924/30101

(57) ABSTRACT

A method for providing power integrity to a semiconductor device can include providing one or more die of a semiconductor device that contains functional circuitry of the semiconductor device. The method can also include stacking one or more semiconductor device layers with the one or more die. The method can additionally include providing, in the one or more semiconductor device layers, metal layers that are configured to provide power integrity to the functional circuitry of the semiconductor device. Various other methods and systems are also disclosed.

### BACKGROUND

An integrated circuit (e.g., an IC, a chip, or a microchip) is a set of electronic circuits on one small flat piece of semiconductor material, usually silicon. Large numbers of miniaturized transistors and other electronic components are integrated together on the chip. Chips containing integrated circuits can be implemented in a semiconductor device.

A semiconductor device is an electronic component that relies on the electronic properties of a semiconductor material (e.g., silicon, germanium, gallium arsenide, and/or organic semiconductors) for its function. Its conductivity lies between conductors and insulators. Semiconductor devices can be implemented in semiconductor device packages.

A semiconductor device package is a metal, plastic, glass, or ceramic casing containing one or more discrete semiconductor devices or integrated circuits. Individual components can be fabricated on semiconductor wafers (e.g., silicon) before being diced into die, tested, and packaged. The package provides a means for connecting it to the external environment, such as printed circuit board, via leads such as lands, balls, or pins; and protection against threats such as mechanical impact, chemical contamination, and light exposure. Additionally, it helps dissipate heat produced by the device, with or without the aid of a heat spreader. Semiconductor device packages can include a package substrate.

A package substrate is a piece of insulator (e.g., a flat piece) on which an integrated circuit can be mounted. For example, input and output pins of an integrated circuit can be individually connected (e.g., by wire bonding or bump bonding) to metal leads on the substrate. These leads can connect the integrated circuit to other parts of the package. The package substrate can be mounted to a printed circuit board.

A three-dimensional integrated circuit (3D IC) is a MOS (metal-oxide semiconductor) integrated circuit (IC) manufactured by stacking as many as 16 or more ICs and interconnecting them vertically using, for instance, through-silicon vias (TSVs) or Cu-Cu connections, so that they behave as a single device to achieve performance improvements at reduced power and smaller footprint than conventional two dimensional processes. The 3D IC is one of several 3D integration schemes that exploit the z-direction to achieve electrical performance benefits in microelectronics and nanoelectronics.

3D integrated circuits can be classified by their level of interconnect hierarchy at the global (package), intermediate (bond pad) and local (transistor) level. In general, 3D integration is a broad term that includes such technologies as 3D wafer-level packaging (3DWLP), 2.5D and 3D interposer-based integration, 3D stacked ICs (3D-SICs), 3D heterogeneous integration, and 3D systems integration as well as true monolithic 3D ICs.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a flow diagram of an example method for providing power integrity to functional circuitry of a semiconductor device.

FIG. 2 is a block diagram of an example semiconductor device including one or more semiconductor device layers having regions that are occupied by dummy silicon.

FIG. 3 is a block diagram of an example semiconductor device that includes metal layers in regions of the one or more semiconductor device layers that would otherwise be occupied by dummy silicon.

FIG. 4 is a block diagram of an example semiconductor device that includes metal layers in regions of a static random access memory die that is extended to match a size of a die containing functional circuitry.

FIG. 5 is a block diagram of an example semiconductor device that includes metal layers in one or more additional semiconductor device layers that add the metal layers.

FIG. 6 is a block diagram of an example semiconductor device that includes metal layers in one or more additional semiconductor device layers that add the metal layers.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

When logic in a semiconductor device draws power, there can be a temporary loss in voltage until a voltage regulator is able to respond. Capacitors between the voltage regulator and the logic (e.g., in the printed circuit board, in the package, in the upper metal of the semiconductor device, transistor wells in the bulk silicon, etc.) can experience this droop. Traditional attempts to address this issue involve adding more capacitors in the package, interposer, and/or printed circuit board.

The present disclosure is generally directed to providing power integrity to functional circuitry of a semiconductor device. For example, the disclosed systems and methods can provide one or more die of a semiconductor device that contains functional circuitry of the semiconductor device, stack one or more semiconductor device layers with the one or more die, and provide, in the one or more semiconductor device layers, metal layers that are configured to provide power integrity to the functional circuitry of the semiconductor device. Adding metal layers (e.g., and optionally capacitors) in layers of a semiconductor device can provide numerous benefits.

Benefits realized by adding metal layers (e.g., and optionally capacitors) in a semiconductor device (e.g., as opposed to or in addition to in the package, interposer, and/or printed circuit board) can include reduction or avoidance of extreme drops in power integrity, voltage drop, transient droop, di/dt, etc. An additional benefit can include achieving higher density capacitance near the locations where power is being drawn, which can aid in mitigating this drop, thus improving ability to maintain high frequencies, achieve power efficiency, etc. In this context, metal layers within the stacked devices advantageously provide access to capacitors that are further away, reducing resistance along that path using, for example, a hybrid bond interface. As a result, a particular hotspot within the device that is drawing a lot of power can draw charge from more capacitors that are further away through a lower resistance channel. Improving power integrity in this manner translates to improving peak performance of functional circuitry of the semiconductor device.

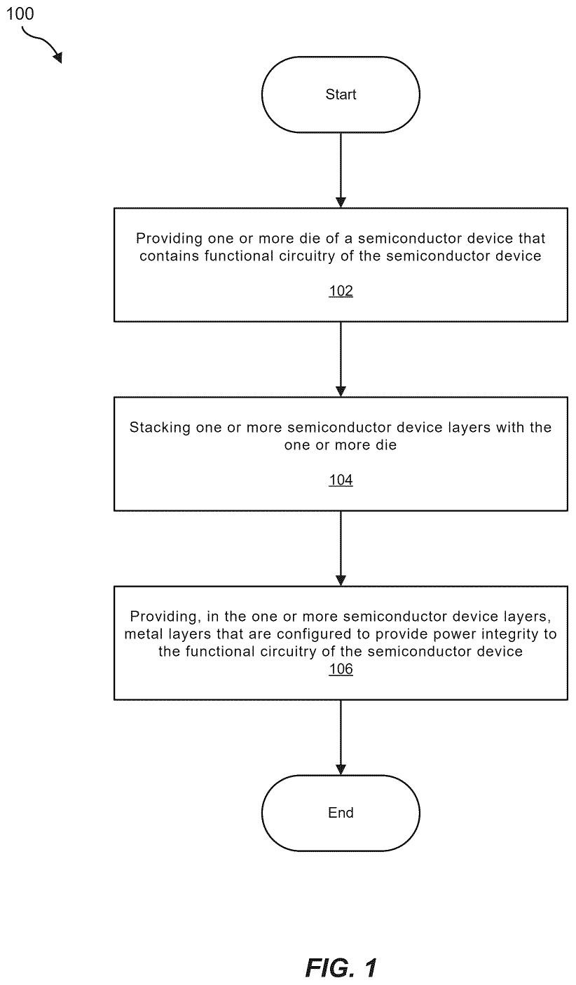

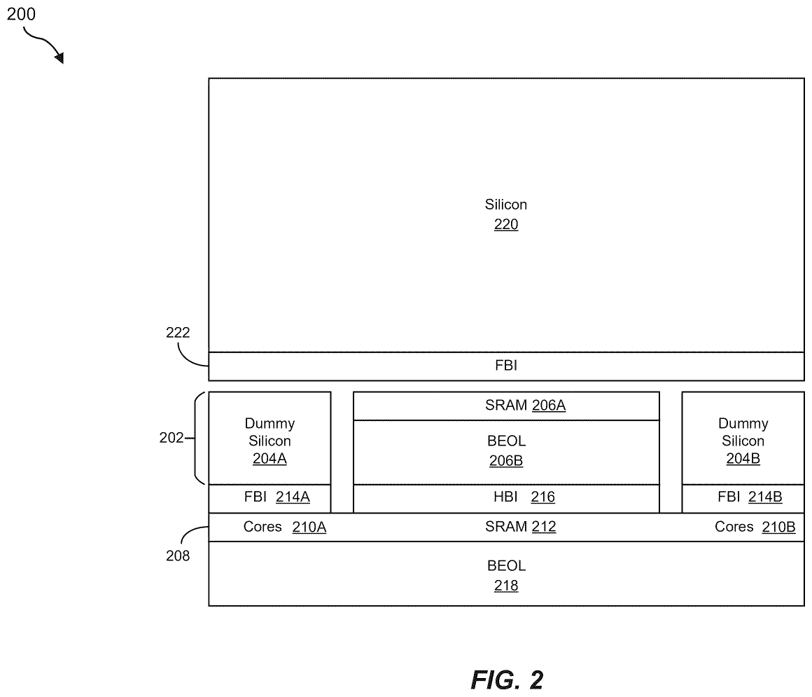

The following will provide, with reference to FIG. 1, detailed descriptions of exemplary methods for providing power integrity to a semiconductor device. In addition, detailed descriptions of example semiconductor devices will be provided in connection with FIGS. 2-6.

In one example, a semiconductor device can include one or more die of the semiconductor device that contains functional circuitry of the semiconductor device and one or more semiconductor device layers stacked with the one or more die, wherein the one or more semiconductor device layers include metal layers configured to provide power integrity to the functional circuitry of the semiconductor device.

Another example can be the previously described example semiconductor device, wherein the one or more semiconductor device layers further include one or more capacitors configured to provide power integrity to the functional circuitry of the semiconductor device.

Another example can be any of the previously described example semiconductor devices, wherein the one or more semiconductor device layers include the metal layers in regions of the one or more semiconductor device layers that would otherwise be occupied by dummy silicon.

Another example can be any of the previously described example semiconductor devices, wherein the one or more semiconductor device layers correspond to one or more additional semiconductor device layers that add the metal layers.

Another example can be any of the previously described example semiconductor devices, wherein the one or more semiconductor device layers are partitioned into one or more circuitry regions that contain additional functional circuitry of the semiconductor device and one or more power integrity regions that include the metal layers and that are positioned at least one of directly above or directly below the functional circuitry.

Another example can be any of the previously described example semiconductor devices, wherein the metal layers are included in one or more regions of a static random access memory die that is extended to match a size of the one or more die.

Another example can be any of the previously described example semiconductor devices, wherein the metal layers are connected to the functional circuitry by a hybrid bond interface.

In one example, a method can include providing one or more die of a semiconductor device that includes functional circuitry of the semiconductor device, stacking one or more semiconductor device layers with the one or more die, and providing, in the one or more semiconductor device layers, metal layers that are configured to provide power integrity to the functional circuitry of the semiconductor device.

Another example can be the previously described example method, further including providing, in the one or more semiconductor device layers, one or more capacitors configured to provide power integrity to the functional circuitry of the semiconductor device.

Another example can be any of the previously described example methods, further including providing the metal layers in regions of the one or more semiconductor device layers that would otherwise be occupied by dummy silicon.

Another example can be any of the previously described example methods, wherein the one or more semiconductor device layers correspond to one or more additional semiconductor device layers that add the metal layers.

Another example can be any of the previously described example methods, further including partitioning the one or more semiconductor device layers into one or more circuitry regions that contain additional functional circuitry of the semiconductor device and one or more power integrity regions that include the metal layers and that are positioned at least one of directly above or directly below the functional circuitry.

Another example can be any of the previously described example methods, further including positioning the metal layers in one or more regions of a static random access memory die that is extended to match a size of the one or more die.

Another example can be any of the previously described example methods, further including connecting the metal layers to the functional circuitry by a hybrid bond interface.

In one example, a system can include one or more semiconductor device layers configured for stacking with one or more die, and metal layers that are located in the one or more semiconductor device layers and that are configured to provide power integrity to functional circuitry in the one or more die.

Another example can be the previously described example system, further including one or more capacitors that are located in the one or more semiconductor device layers and that are configured to provide power integrity to the functional circuitry.

Another example can be any of the previously described example systems, wherein the metal layers are located in regions of the one or more semiconductor device layers that would otherwise be occupied by dummy silicon.

Another example can be any of the previously described example systems, wherein the one or more semiconductor device layers correspond to one or more additional semiconductor device layers that add the metal layers.

Another example can be any of the previously described example systems, wherein the metal layers are included in one or more regions of a static random access memory die that is extended to match a size of the one or more die.

Another example can be any of the previously described example systems, wherein the metal layers are connected to the functional circuitry by a hybrid bond interface.

FIG. 1 is a flow diagram of an example method 100 for providing power integrity to a semiconductor device. As illustrated in FIG. 1 at step 102, method 100 can include providing a die. For example, method 100 can, at step 102, provide one or more die of a semiconductor device that contains functional circuitry of the semiconductor device.

The term “power integrity,” as used herein, can generally refer to any measure, structure, or process implemented to ensure that required voltage and currents are delivered from source to load within a system. For example, and without limitation, providing power integrity to a semiconductor device can entail ensuring that its power delivery network is designed to provide stable voltage references and to distribute power to all of the board components within acceptable noise and tolerance levels.

The term “core compute die,” as used herein, can generally refer to a piece of silicon that includes a plurality of processor cores. For example, and without limitation, a core compute die can house one or more chiplets each including multiple (e.g., four) processor cores.

The systems described herein can implement step 102 in a variety of ways. For example, method 100 can, at step 102, provide a die containing one or more processor cores and/or static random access memory (SRAM). In some implementations, the die can include two processor cores located in peripheral regions of the die and SRAM located in a central region of the die.

As illustrated in FIG. 1 at step 104, method 100 can include stacking one or more layers. For example, method 100 can, at step 104, stack one or more semiconductor device layers with the one or more die.

The term “semiconductor device layer,” as used herein, can generally refer to a semiconductor wafer or one or more chips arranged two dimensionally to form a layer of a 3D stack. For example, semiconductor device layers can be formed using wafer on wafer and/or chip on wafer processes.

The systems described herein can implement step 104 in a variety of ways. For example, method 100 can, at step 104, stack one or more semiconductor device layers that correspond to one or more additional semiconductor device layers that add metal layers.

As illustrated in FIG. 1 at step 106, method 100 can include providing metal layers. For example, method 100 can, at step 106, provide, in the one or more semiconductor device layers, metal layers that are configured to provide power integrity to the functional circuitry of the semiconductor device.

The term “metal layer,” as used herein, can generally refer to wiring in and/or on a wafer and/or chip that interconnects individual devices (e.g., transistors, capacitors, resistors, etc.) of an integrated circuit. For example, and without limitation, a metal layer can include copper and/or aluminum.

The systems described herein can implement step 102 in a variety of ways. For example, method 100 can, at step 106, provide, in the one or more semiconductor device layers, one or more capacitors configured to provide power integrity to the functional circuitry of the semiconductor device. In another example, method 100 can, at step 106, provide the metal layers in regions of the one or more semiconductor device layers that would otherwise be occupied by dummy silicon. In another example, method 100 can, at step 106, position the metal layers in one or more regions of a static random access memory die that is extended to match a size of the one or more die. Extending the static random access memory die in this manner can allow for a wafer on wafer process. In another example, method 100 can, at step 106, partition one or more semiconductor device layers into one or more circuitry regions that contain additional functional circuitry of the semiconductor device and one or more power integrity regions that include the metal layers and that are positioned at least one of directly above or directly below the functional circuitry. In another example, method 100 can, at step 106, connect the metal layers to the one or more die by a hybrid bond interface. Connecting the metal layers to the die in this manner can achieve a low resistance channel allowing a particular hotspot within the semiconductor device that is drawing a lot of power to draw charge from more metal layers (e.g., and optionally capacitors) that are further away.

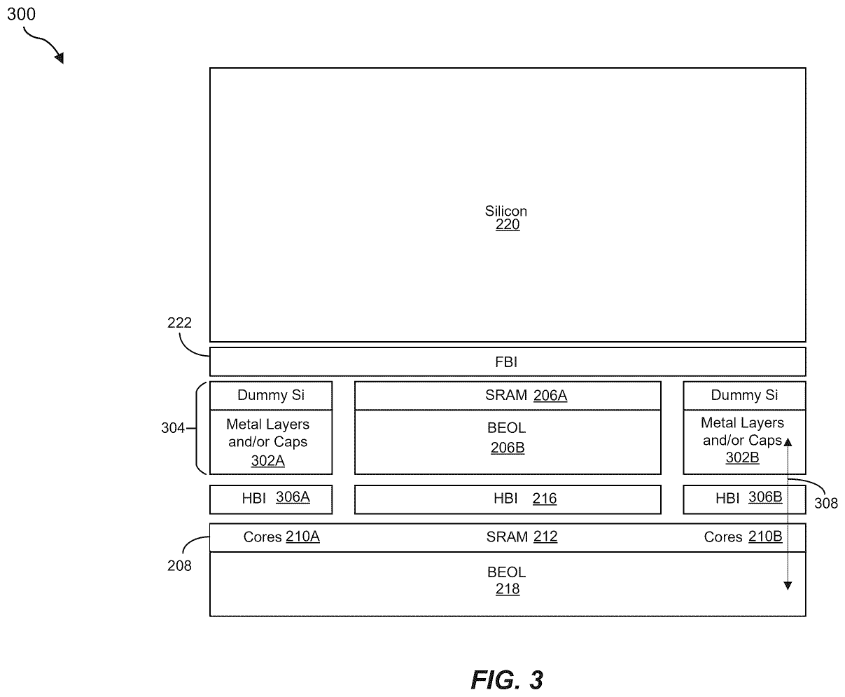

The phrase “directly above or directly below,” as used herein, can generally refer to a position above or below but not entirely off to one side. For example, and without limitation, one thing located in one die can be positioned directly above or directly below an additional thing located in an additional die if a line orthogonal to planes and/or longitudinal axes of the die intersects the one thing and the additional thing. Examples of metal layers positioned directly above and/or directly below functional circuitry are shown in FIGS. 3-6 and detailed later herein with reference thereto.

FIG. 2 illustrates an example semiconductor device 200 including a semiconductor device layer 202 having regions 204A and 204B that can be occupied by dummy silicon. semiconductor device layer 202 can also include sublayer regions 206A and 206B that respectively can contain static random access memory (SRAM) and back end of line (BEOL). semiconductor device layer 202 can be located above a core compute die 208 that can correspond to another layer of the semiconductor device 200. Core compute die can include processor cores 210A and 210B located at a periphery thereof and SRAM 212 located at a center thereof. Regions 204A and 204B can be located above the processor cores 210A and 210B and connected thereto by fusion bond interfaces (FBIs) 214A and 214B. SRAM contained in sublayer regions 206A can be located above SRAM 212 and connected thereto by BEOL contained in sublayer region 206B and by a hybrid bond interface (HBI) 216. Semiconductor device 200 can also include layers 218 and 220. Layer 218 can be located below the core compute die 208 and can include BEOL whereas layer 220 can be located above semiconductor device layer 202, can contain silicon, and can be connected to semiconductor device layer 202 by FBI 222. The regions 204A and 204B, sublayer regions 206A and 206B, FBIs 214A and 214B, and HBI 216 can correspond to chips that are dies of size smaller than the core compute die 208. Thus semiconductor device 200 can be constructed utilizing a chip on wafer process. Semiconductor device 200 serves as an example device that can be improved by implementation of the methods described above with reference to FIG. 1, various example implementations of which are detailed below with reference to FIGS. 3-6.

FIG. 3 illustrates an example semiconductor device 300 that includes metal layers in regions 302A and 302B of a semiconductor device layer 304 that would otherwise be occupied by dummy silicon. Semiconductor device 300 can include many of the components detailed above with reference to semiconductor device 200 of FIG. 2. For example, semiconductor device 300 can include sublayer regions 206A and 206B, core compute die 208, processor cores 210A and 210B, SRAM 212, HBI 216, layers 218 and 220, and FBI 222. However, rather than merely containing dummy silicon in regions 302A and 302B, at least part of these regions 302A and 302B can contain metal layers. In some implementations, at least part of these regions 302A and 302B additionally can contain capacitors. Moreover, instead of being connected to processor cores 210A and 210B by FBIs as in FIG. 2, regions 302A and 302B can be connected to processor cores 210A and 210B by HBIs 306A and 306B. By locating the metal layers and, optionally, capacitors proximate to the processor cores 210A and 210B and providing a low resistance channel 308 thereto using HBIs 306A and 306B, improved peak performance of the processor cores 210A and 210B can be achieved due to improved power integrity realized by enabling the processor cores 210A and 210B to draw power from the metal layers (e.g., and optionally capacitors) by a low resistance path provided by the HBIs 306A and 306B. The sublayer regions 206A and 206B, HBI 216, regions 302A and 302B, and HBI 306A and 306B can correspond to chips that are dies of size smaller than the core compute die 208. Thus semiconductor device 200 can be constructed utilizing a chip on wafer process.

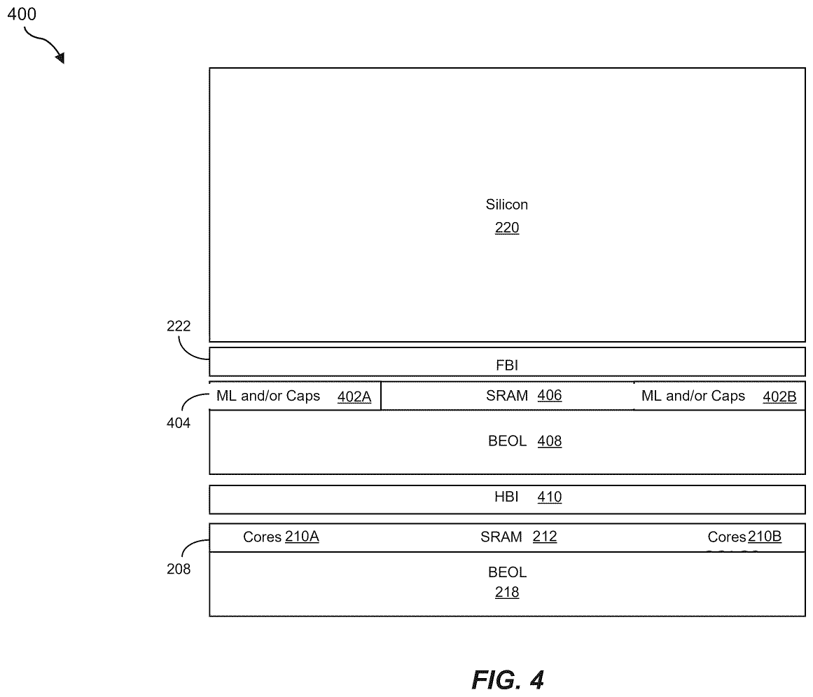

FIG. 4 illustrates an example semiconductor device 400 that includes metal layers in regions 402A and 402B of an SRAM die 404 that is extended. Semiconductor device 400 can include many of the components detailed above with reference to semiconductor device 200 of FIG. 2, and semiconductor device 300 of FIG. 3. For example, semiconductor device 400 can include core compute die 208, processor cores 210A and 210B, SRAM 212, layers 218 and 220, and FBI 222. However, unlike region 206A of FIGS. 2 and 3 (e.g., a die corresponding to a chip implemented using a chip on wafer process), SRAM die 404 can be extended to match a size of a core compute die 208. This extension can be implemented by adding the regions 402A and 402B that contain the metal layers (e.g., and optionally capacitors) at a periphery of the SRAM die and retaining the SRAM in a central region 406 of the SRAM die 404. Extending the SRAM die 404 to match the size of the core compute die enables semiconductor device 400 to be constructed utilizing a wafer on wafer process. This capability can be further facilitated by similarly extending BEOL 408 and HBI 410 to match the size of the core compute die 208. By implementing all layers of the semiconductor device 400 as dies having a same size as the core compute die 208, the semiconductor device 400 can be constructed according to a wafer on wafer process, resulting in reduced costs and/or cycle time. Further, by locating the metal layers and, optionally, capacitors proximate to the processor cores 210A and 210B and providing a low resistance channel thereto using HBI 410, improved peak performance of the processor cores 210A and 210B can be achieved due to improved power integrity realized by enabling the processor cores 210A and 210B to draw power from the metal layers (e.g., and optionally capacitors) by a low resistance path provided by HBI 410.

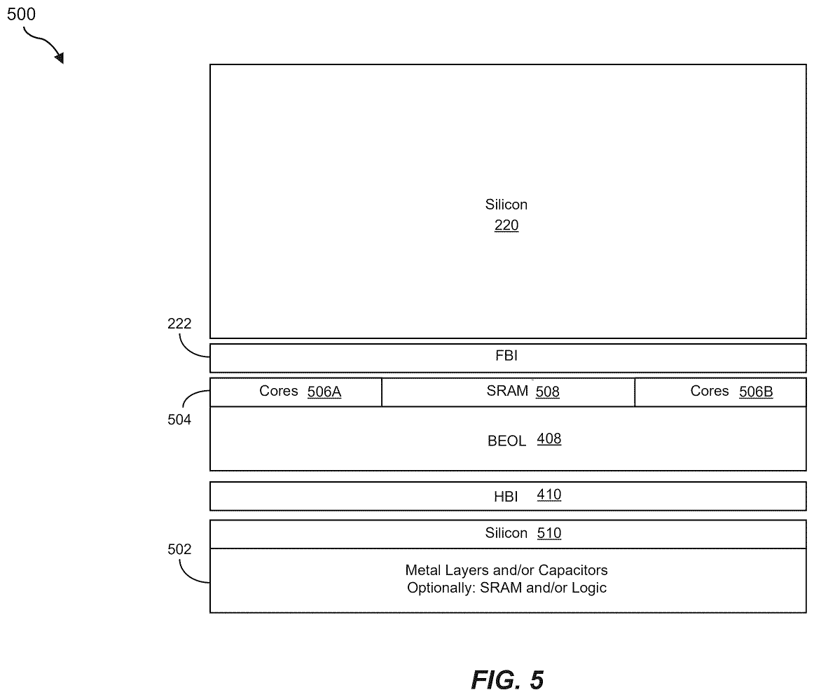

FIG. 5 illustrates an example semiconductor device 500 that includes metal layers in an additional semiconductor device layer 502 that adds the metal layers. Semiconductor device 500 can include many of the components detailed above with reference to semiconductor device 200 of FIG. 2, semiconductor device 300 of FIG. 3, and semiconductor device 400 of FIG. 4. For example, semiconductor device 500 can include layer 220, FBI 222, BEOL 408, and HBI 410. Additionally, semiconductor device 500 can include a core compute die 504 that can include processor cores 506A and 506B and SRAM 508, and core compute die 504 can be the same or similar to core compute die 208 of FIGS. 2-4 except that it can be positioned between FBI 222 and BEOL 408. Semiconductor device 500 can also include a silicon layer 510 located between HBI 410 and the additional semiconductor device layer 502. The additional semiconductor device layer can include metal layers and, optionally, capacitors, SRAM, and/or logic elements. In some implementations, the metal layers and, optionally, capacitors, can be located directly below the processor cores 506A at peripheral regions of the additional semiconductor device layer 502 and SRAM and/or logic elements can be located in a central region of the additional semiconductor device layer 502 below SRAM 508. Additionally or alternatively, the metal layers and, optionally, capacitors, can be located directly below SRAM 508 and provide power integrity to SRAM 508. By implementing all layers of the semiconductor device 500 as dies having a same size as that of the core compute die 504, the semiconductor device 500 can be constructed according to a wafer on wafer process, resulting in reduced costs and/or cycle time. Further, by locating the metal layers and, optionally, capacitors proximate to functional circuitry (e.g., the processor cores 506A and 506B and/or SRAM 508) and providing a low resistance channel thereto using HBI 410, improved peak performance of the processor cores 506A and 506B and/or SRAM 508 can be achieved due to improved power integrity realized by enabling the processor cores 506A and 506B to draw power from the metal layers (e.g., and optionally capacitors) by a low resistance path provided by HBI 410.

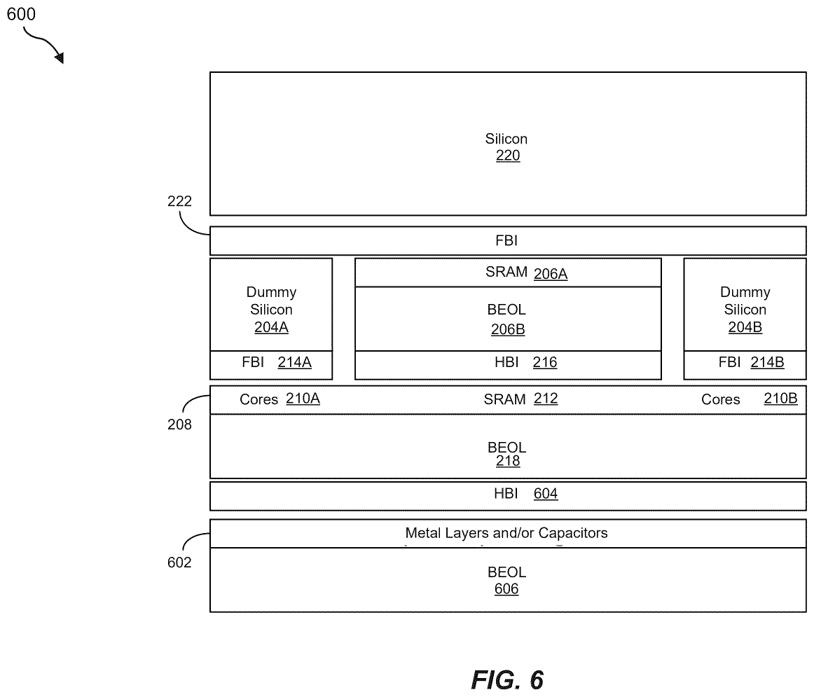

FIG. 6 illustrates an example semiconductor device 600 that includes metal layers in an additional semiconductor device layer 602 that adds the metal layers. Semiconductor device 600 can include many of the components detailed above with reference to semiconductor device 200 of FIG. 2. For example, semiconductor device 600 can include regions 204A and 204B, sublayer regions 206A and 206B, core compute die 208, processor cores 210A and 210B, SRAM 212, FBIs 214A and 214B, HBI 216, layers 218 and 220, and FBI 222. Additionally, semiconductor device 600 can include HBI 604 positioned below layer 218, the additional semiconductor device layer 602 positioned below HBI 604, and BEOL 606 positioned below the additional semiconductor device layer 602. Thus, the additional semiconductor device layer 602 can add the metal layers and, optionally, capacitors below the processor cores 210A and 210B and/or

SRAM 212. By locating the metal layers and, optionally, capacitors proximate to the processor cores 210A and 210B and/or SRAM 212 and providing a low resistance channel thereto using HBI 604, improved peak performance of the processor cores 210A and 210B and/or SRAM 212 can be achieved due to improved power integrity realized by enabling the processor cores 210A and 210B and/or SRAM 212 to draw power from the metal layers (e.g., and optionally capacitors) by a low resistance path provided by HBI 604.

As set forth above, the disclosed systems and methods can provide one or more die of a semiconductor device that contains functional circuitry of the semiconductor device, stack one or more semiconductor device layers with the one or more die, and provide, in the one or more semiconductor device layers, metal layers that are configured to provide power integrity to the functional circuitry of the semiconductor device. Adding metal layers (e.g., and optionally capacitors) in layers of a semiconductor device can provide numerous benefits.

Benefits realized by adding metal layers (e.g., and optionally capacitors) in a semiconductor device (e.g., as opposed to or in addition to in the package, interposer, and/or printed circuit board) can include reduction or avoidance of extreme drops in power integrity, voltage drop, transient droop, di/dt, etc. An additional benefit can include achieving higher density capacitance near the locations where power is being drawn, which can aid in mitigating this drop, thus improving ability to maintain high frequencies, achieve power efficiency, etc. In this context, metal layers within the stacked devices advantageously provide access to capacitors that are further away, reducing resistance along that path using, for example, a hybrid bond interface. As a result, a particular hotspot within the device that is drawing a lot of power can draw charge from more capacitors that are further away through a lower resistance channel. Improving power integrity in this manner translates to improving peak performance of functional circuitry of the semiconductor device.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor device, comprising:
one or more die of the semiconductor device that contains functional circuitry of the semiconductor device; and
one or more semiconductor device layers stacked with the one or more die, wherein the one or more semiconductor device layers include metal layers configured to provide power integrity to the functional circuitry of the semiconductor device.

2. The semiconductor device of claim 1, wherein the one or more semiconductor device layers further include one or more capacitors configured to provide power integrity to the functional circuitry of the semiconductor device.

3. The semiconductor device of claim 1, wherein the one or more semiconductor device layers include the metal layers in regions of the one or more semiconductor device layers that would otherwise be occupied by dummy silicon.

4. The semiconductor device of claim 1, wherein the one or more semiconductor device layers correspond to one or more additional semiconductor device layers that add the metal layers.

5. The semiconductor device of claim 1, wherein the one or more semiconductor device layers are partitioned into:
one or more circuitry regions that contain additional functional circuitry of the semiconductor device; and
one or more power integrity regions that include the metal layers and that are positioned at least one of directly above or directly below the functional circuitry.

6. The semiconductor device of claim 1, wherein the metal layers are included in one or more regions of a static random access memory die that is extended to match a size of the one or more die.

7. The semiconductor device of claim 1, wherein the metal layers are connected to the functional circuitry by a hybrid bond interface.

8. A method, comprising:
providing one or more die of a semiconductor device that contains functional circuitry of the semiconductor device;
stacking one or more semiconductor device layers with the one or more die; and
providing, in the one or more semiconductor device layers, metal layers that are configured to provide power integrity to the functional circuitry of the semiconductor device.

9. The method of claim 8, further comprising:
providing, in the one or more semiconductor device layers, one or more capacitors configured to provide power integrity to the functional circuitry of the semiconductor device.

10. The method of claim 8, further comprising:
providing the metal layers in regions of the one or more semiconductor device layers that would otherwise be occupied by dummy silicon.

11. The method of claim 8, wherein the one or more semiconductor device layers correspond to one or more additional semiconductor device layers that add the metal layers.

12. The method of claim 8, further comprising:
partitioning the one or more semiconductor device layers into:
one or more circuitry regions that contain additional functional circuitry of the semiconductor device; and
one or more power integrity regions that include the metal layers and that are positioned at least one of directly above or directly below the functional circuitry.

13. The method of claim 11, further comprising:
positioning the metal layers in one or more regions of a static random access memory die that is extended to match a size of the one or more die.

14. The method of claim 11, further comprising:
connecting the metal layers to the functional circuitry by a hybrid bond interface.

15. A system, comprising:
one or more semiconductor device layers configured for stacking with one or more die; and
metal layers that are located in the one or more semiconductor device layers and that are configured to provide power integrity to functional circuitry located in the one or more die.

16. The system of claim 15, further comprising:
one or more capacitors that are located in the one or more semiconductor device layers and that are configured to provide power integrity to the functional circuitry.

17. The system of claim 15, wherein the metal layers are located in regions of the one or more semiconductor device layers that would otherwise be occupied by dummy silicon.

18. The system of claim 15, wherein the one or more semiconductor device layers correspond to one or more additional semiconductor device layers that add the metal layers.

19. The system of claim 15, wherein the metal layers are included in one or more regions of a static random access memory die that is extended to match a size of the one or more die.

20. The system of claim 15, wherein the metal layers are connected to the functional circuitry by a hybrid bond interface.
